(19) United States
(12) Patent Application Publication
(10) Pub. No.: US 2017/0236705 A1
(43) Pub. Date: Aug. 17, 2017

(54) Low Temperature Poly-Silicon Thin Film, Low-Temperature Poly-Silicon Thin Film Transistor and Manufacturing Methods Thereof, and Display Device

(71) Applicant: BOE TECHNOLOGY GROUP CO., LTD., Beijing (CN)

(72) Inventors: Dong LI, Beijing (CN); Xiaoyong LU, Beijing (CN); Xiaolong LI, Beijing (CN); Zheng LIU, Beijing (CN); Shuai ZHANG, Beijing (CN); Yucheng CHAN, Beijing (CN); Chienhung LIU, Beijing (CN); Chunping LONG, Beijing (CN)

(21) Appl. No.: 15/518,642

(22) PCT Filed: Jan. 22, 2016
(86) PCT No.: PCT/CN2016/071715

§ 371 Date: Apr. 12, 2017

(30) Foreign Application Priority Data
Aug. 14, 2015 (CN) 201510502838.5

(51) Int. Cl. H01L 21/02; H01L 29/786; H01L 27/12; H01L 29/66

(52) U.S. Cl. CPC H01L 21/0268; H01L 21/02532; H01L 21/02592; H01L 21/02488; H01L 29/66757; H01L 29/78675; H01L 27/1222; H01L 27/1285

(57) ABSTRACT

The present application provides a low temperature poly-silicon thin film, a low temperature poly-silicon thin film transistor and manufacturing methods thereof, and a display device. The manufacturing method of a low temperature poly-silicon thin film comprises steps of: forming an amorphous silicon thin film on a base; and performing a laser annealing process on the amorphous silicon thin film by using a mask plate to form a low temperature poly-silicon thin film, wherein the mask plate includes a transmissive region and a shielding region surrounding the transmissive region, and two sides of the shielding region adjacent to the transmissive region are in concave-convex shapes. Performance of the low temperature poly-silicon thin film formed by the manufacturing method of a low temperature poly-silicon thin film in the present application is enhanced.

### TECHNICAL FIELD

The present application relates to the field of display technology, and particularly, to a low temperature poly-silicon thin film, a low temperature poly-silicon thin film transistor and manufacturing methods thereof, and a display device.

### BACKGROUND ART

With the development of the display technology, people's demands on the display quality is increasing, thus tablet display devices with high image quality and high resolution are popular more and more and attract importance of the manufacturers more and more.

A thin film transistor (TFT) is a main driving device in a tablet display panel and plays a key role in the development direction of the high performance tablet display devices. Thin film transistors may have a variety of structures and thus there are many materials for manufacturing the thin film transistors with different structures, for example, an amorphous silicon and a poly-silicon are common materials for manufacturing the thin film transistors. However, the amorphous silicon self has many inherent disadvantages, for example, low mobility and low stability etc., and in contrast, the low temperature poly-silicon (LTPS) has higher mobility and stability and the mobility of the LTPS may be up to tens or even hundreds times as high as that of the amorphous silicon. Therefore, a technique for manufacturing the thin film transistor using the LTPS has been developed rapidly, and a new generation liquid crystal display (LCD) or an organic light emitting diode (OLED) derived from the LTPS, especially the OLED, becomes an important display technology. The OLED has been favored by users due to its characteristics of ultra-thin, low power consumption and self luminous.

Though the LTPS has above advantages, since a low temperature poly-silicon thin film (i.e., an active layer) of the low temperature poly-silicon thin film transistor (LTPS TFT) is formed by performing a laser annealing process on the low temperature poly-silicon thin film, non-uniformity of the grain size of poly-silicon and large surface roughness of the low temperature poly-silicon thin film may be occurred in the laser annealing process, resulting poor uniformities of the threshold voltage and mobility of the low temperature poly-silicon thin film transistor, especially when the size of the transistor is decreased, the non-uniformity of the threshold voltage will become more serious.

### SUMMARY

In view of the above technical problem existed in the low temperature poly-silicon thin film, the present invention provides a low temperature poly-silicon thin film, which has good uniformity and can improve the performance of a transistor, a low temperature poly-silicon thin film transistor and manufacturing methods thereof, and a display device.

A technical solution adopted to solve the above technical problem is a manufacturing method of a low temperature poly-silicon thin film, comprising steps of:

forming an amorphous silicon thin film on a base; and

performing a laser annealing process on the amorphous silicon thin film by using a mask plate to form a low temperature poly-silicon thin film, wherein

the mask plate includes a transmissive region and a shielding region surrounding the transmissive region, and two opposite sides of the shielding region adjacent to the transmissive region are in concave-convex shapes.

Optionally, in the step of performing a laser annealing process on the amorphous silicon thin film by using a mask plate, a scanning direction of a laser is parallel to an orientation direction of peaks of the concave-convex shape.

Optionally, in the step of performing a laser annealing process on the amorphous silicon thin film by using a mask plate, an energy density of the laser is from 350 mJ/cm² to 550 mJ/cm².

Optionally, in the step of performing a laser annealing process on the amorphous silicon thin film by using a mask plate, a pulse width of the laser is from 30 ns to 200 ns.

Optionally, before the step of forming an amorphous silicon thin film on a base, the method further comprises a step of forming a buffer layer on the base.

Further optionally, the buffer layer comprises at least one of a silicon oxide layer and a silicon nitride layer.

Further optionally, a thickness of the buffer layer is from 150 nm to 300 nm.

Optionally, the peaks of the concave-convex shape are distributed at uniform intervals and a distance between two adjacent peaks is from 0.3 μm to 2 μm.

Optionally, the concave-convex shape is a triangular wave shape or a wave shape.

Optionally, the laser annealing process is an excimer laser annealing process or a continuous wave solid-state laser annealing process.

A technical solution adopted to solve the above technical problem is a low temperature poly-silicon thin film, which is manufactured by using the above manufacturing method.

A technical solution adopted to solve the above technical problem is manufacturing method of a low temperature poly-silicon thin film transistor, which comprises the above manufacturing method of a low temperature poly-silicon thin film.

A technical solution adopted to solve the above technical problem is a manufacturing method of a low temperature poly-silicon thin film transistor, comprising a step of forming an active layer, wherein the step of forming an active layer comprises steps of:

forming an amorphous silicon thin film on a base;

performing a laser annealing process on the amorphous silicon thin film by using a mask plate to form a low temperature poly-silicon thin film, wherein the mask plate includes a transmissive region and a shielding region surrounding the transmissive region, and two opposite sides of the shielding region adjacent to the transmissive region are in concave-convex shapes; and

performing a patterning process on the low temperature poly-silicon thin film to form a pattern including the active layer.

Optionally, before the step of forming an amorphous silicon thin film on a base, the method further comprises a step of forming a buffer layer on the base.

Optionally, in the step of performing a laser annealing process on the amorphous silicon thin film by using a mask plate, a scanning direction of a laser is parallel to an orientation direction of peaks of the concave-convex shape.

Further optionally, after the formation of the pattern including the active layer, the method further comprises a step of forming a pattern including a source and a drain by using a patterning process, wherein a direction of a center connection line connecting centers of the source and the drain is parallel to a scanning direction of the laser.

A technical solution adopted to solve the above technical problem is a low temperature poly-silicon thin film transistor, which is manufactured by using the above manufacturing method.

A technical solution adopted to solve the above technical problem is a display device comprising the above low temperature poly-silicon thin film transistor.

The present invention has following advantages:

In the present invention, a mask plate for performing a laser annealing process on a amorphous silicon thin film is used in the manufacturing method of a low temperature poly-silicon thin film to form the low temperature poly-silicon thin film, the mask plate including a transmissive region and a shielding region surrounding the transmissive region, and two opposite sides of the shielding region adjacent to the transmissive region being in concave-convex shapes, thus the low temperature poly-silicon thin film formed by the laser annealing process will grow by taking the amorphous silicon at peaks not being irradiated as crystal nucleuses. Therefore, the grain size and grain boundary position of the low temperature poly-silicon thin film are improved, and when the low temperature poly-silicon thin film is used in a thin film transistor, the electric characteristics of the transistor can be enhanced.

### BRIEF DESCRIPTION OF THE DRAWINGS

FIG. 1 is a flowchart of a manufacturing method of a low temperature poly-silicon thin film in a first embodiment of the present disclosure;

FIG. 1 is a schematic diagram of a mask plate adopted in the manufacturing method of a low temperature poly-silicon thin film in the first embodiment of the present disclosure;

FIG. 3 is a schematic diagram of a low temperature poly-silicon thin film manufactured by the manufacturing method of a low temperature poly-silicon thin film in the first embodiment of the present disclosure;

FIG. 4 is a flowchart of a manufacturing method of a low temperature poly-silicon thin film in a second embodiment of the present disclosure;

FIG. 5 is a flowchart of forming an active layer in the second embodiment of the present disclosure;

FIG. 6 is a schematic diagram illustrating a relationship between positions of a source and a drain and the active layer in the second embodiment of the present disclosure;

reference numerals: 10—mask plate; Q1—transmissive region; Q2—shielding region; 20—amorphous silicon thin film not being irradiated; 21—low temperature poly-silicon thin film; 31—source contact area; 32—drain contact area; and 33—channel region.

### DETAILED DESCRIPTION OF THE EMBODIMENTS

In order to make a person skilled in the art better understand solutions of the present disclosure, the present disclosure will be described in detail below with reference to the accompanying drawings and specific embodiments.

In the embodiments of the present disclosure, a patterning process may comprise only a photolithographic process, or comprise a photolithographic process and an etching process, additionally, it may further comprise other processes such as a printing process and an inkjet process, which are used to form predetermined patterns. The photolithographic process refers to a process for forming patterns by using a photoresist, a mask plate and an exposure machine and the like, which includes a film forming, an exposure and a development process procedures and the like. The patterning process may be selected according to a structure to be formed in the present disclosure.

### First Embodiment

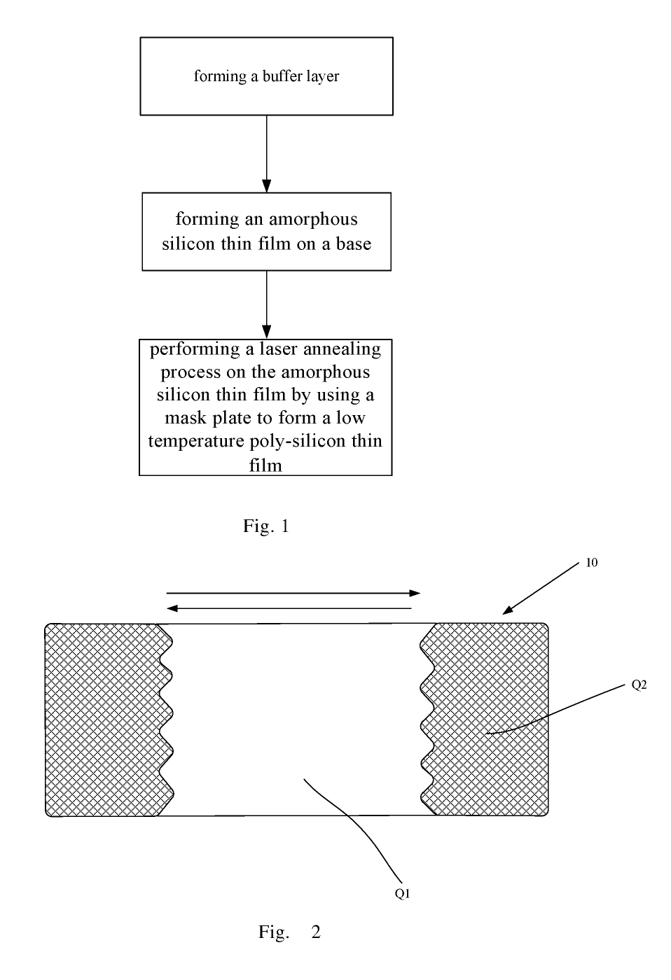

As shown in FIGS. 1-3, the present embodiment provides a manufacturing method of a low temperature poly-silicon thin film, comprising the following steps.

Step 1, forming a buffer layer on a base.

In this step, the base is formed of a transparent material such as glass and is cleaned in advance. Specifically, the buffer layer is formed on the base 1 by using a sputtering method, a thermal evaporation method, a Plasma Enhanced Chemical Vapor Deposition (PECVD) method, a Low Pressure Chemical Vapor Deposition (LPCVD) method, an Atmospheric Pressure Chemical Vapor Deposition (APCVD) method or an Electron Cyclotron Resonance Chemical Vapor Deposition (ECR-CVD) method.

The buffer layer comprises at least one of a silicon oxide layer and a silicon nitride layer. Additionally, a thickness of the buffer layer is from 150 nm to 300 nm. The reason for manufacturing the buffer layer with such thickness is to form an effective heat resistance layer, so that an amorphous silicon may be fully crystallized to form a poly-silicon in subsequent steps.

Step 2, forming an amorphous silicon (a-Si) thin film on the base subjected to the above step.

In this step, the methods for forming the amorphous silicon thin film include a Plasma Enhanced Chemical Vapor Deposition method and a Low Pressure Chemical Vapor Deposition method.

Step 3, performing a laser annealing process on the amorphous silicon thin film by using a mask plate 10 to form a low temperature poly-silicon thin film, wherein the mask plate 10 includes a transmissive region Q1 and a shielding region Q2 surrounding the transmissive region Q1, and two sides of the shielding region Q2 adjacent to the transmissive region Q1 are in concave-convex shapes, as shown in FIG. 2.

This step specifically comprises: disposing the mask plate 10 directly above the base formed with the amorphous silicon thin film thereon first, wherein each of the two sides of the shielding region Q2 adjacent to the transmissive region Q1 of the mask plate 10, which is in concave-convex shape, has a plurality of peaks distributed at uniform intervals, and a distance between two adjacent peaks is from 0.3 μm to 2 μm. The concave-convex shape may be a triangular wave shape or a wave shape, and certainly, it may also be other shapes, such as a sine wave and a square wave.

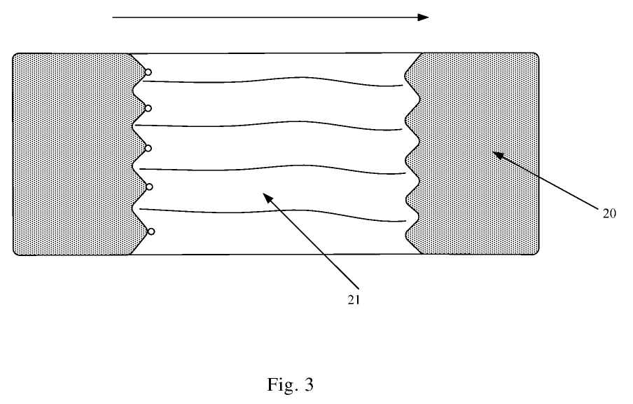

Then, the amorphous silicon thin film is crystallized by using an excimer laser annealing process or a continuous wave solid-state laser annealing process through the mask plate 10. It should be understood that the laser may only pass through the transmissive region Q1 of the mask plate 10 to irradiate on the amorphous silicon thin film, and the amorphous silicon thin film irradiated by the laser will be melted to convert from solid state amorphous silicon thin film into a liquid silicon. Due to shielding of the shielding region Q2 of the mask plate 10, other regions of the amorphous silicon thin film are not irradiated by the laser, thus the amorphous silicon thin film in these regions are not melted and maintain a solid state, and a pattern of not melted amorphous silicon thin film 20 at a boundary of the not melted amorphous silicon thin film 20 and the melted amorphous silicon thin film is identical with the side of the shielding region Q2 of the mask plate 10 adjacent to the transmissive region Q1, which is in the concave-convex shape. The liquid silicon at the boundary of the not melted amorphous silicon thin film 20 and the melted amorphous silicon thin film is epitaxially grown along the peaks by taking the solid-state silicon at the boundary as crystal nucleuses at first to form a low temperature poly-silicon thin film 21. Assuming that the crystal nucleuses have the same growth speed, a position affecting a region away from the boundary most is a position of the crystal nucleus at a peak far away from the boundary, that is, each small circle at each peak as shown in FIG. 3. Therefore, distances between the peaks of the not melted amorphous silicon thin film 20 may be adjusted during manufacturing to adjust the grain size and grain boundary location, so as to improve the uniformity of the formed low temperature poly-silicon thin film 21.

Optionally, in the above step, a scanning direction of the laser is parallel to an orientation direction of peaks of the concave-convex shape, that is, the direction indicated by arrows at top of FIGS. 2-3. The reason for making the laser scan in a direction parallel to the orientation direction of peaks of the concave-convex shape is that what are in this direction are single grains, and the mobility of carriers may be increased significantly by pulling the single grains into straight lines, as shown in FIG. 3.

In the above step of performing the laser annealing process on the amorphous silicon thin film by using the mask plate 10, an energy density of the laser is preferably from 350 mJ/cm² to 550 mJ/cm² to ensure that the irradiated amorphous silicon thin film is completely melted. Certainly, the energy density of the laser may be adjusted according to the thickness of the amorphous silicon thin film.

In the step of performing the laser annealing process on the amorphous silicon thin film by using the mask plate 10, a pulse width of the laser is from 30 ns to 200 ns to ensure that the crystal nucleus has enough growth time in the horizontal direction (that is, the orientation direction of the peaks).

It should be noted that the formed low temperature poly-silicon thin film in the embodiment is not a whole layer, but is formed by forming a part of an amorphous silicon thin film layer (regions irradiated by the laser) as the low temperature poly-silicon thin film. In a practical application, the remained regions of the amorphous silicon thin film may be partly or completely removed through a patterning process.

Moreover, in the embodiment, the manufacturing method of the low temperature poly-silicon thin film may only comprise step 2 and step 3, and step 1 of forming the buffer layer on the base may be omitted according to design requirements. In case of omitting step 1, step 2 is for forming an amorphous silicon thin film on a base

Accordingly, as shown in FIG. 3, the embodiment further provides a low temperature poly-silicon thin film 21, which is manufactured by using the above method. Therefore, the grain size and grain boundary position of the low temperature poly-silicon thin film 21 of the embodiment is improved, when the low temperature poly-silicon thin film 21 is applied to a transistor, the electric characteristics of the transistor can be enhanced.

### Second Embodiment

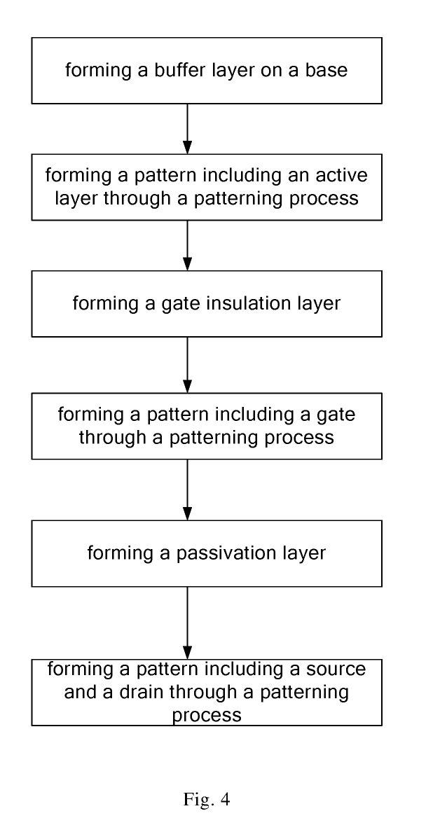

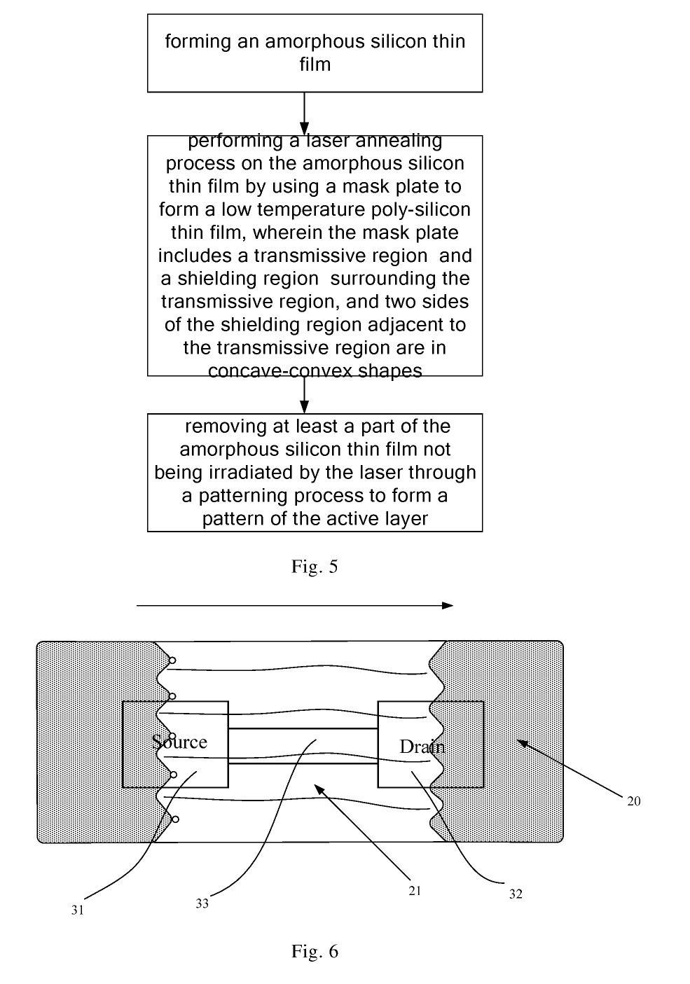

As shown in FIGS. 4-5, the present embodiment provides a manufacturing method of a low temperature poly-silicon thin film transistor, which comprises the manufacturing method of a low temperature poly-silicon thin film of the first embodiment. Specifically, illustration will be given below by taking manufacturing a top-gate type transistor as an example.

Step 1, forming a buffer layer on a base.

In this step, the base is formed of a transparent material such as glass and is cleaned in advance. Specifically, the buffer layer is formed on the base 1 by using a sputtering method, a thermal evaporation method, a Plasma Enhanced Chemical Vapor Deposition (PECVD) method, a Low Pressure Chemical Vapor Deposition (LPCVD) method, an Atmospheric Pressure Chemical Vapor Deposition (APCVD) method or an Electron Cyclotron Resonance Chemical Vapor Deposition (ECR-CVD) method.

The buffer layer comprises at least one of a silicon oxide layer and a silicon nitride layer. Additionally, a thickness of the buffer layer is from 150 nm to 300 nm. The reason for manufacturing the buffer layer with such thickness is to form an effective heat resistance layer, so that an amorphous silicon may be fully crystallized to form a poly-silicon in subsequent steps.

Step 2, forming a pattern including an active layer on the base subjected to the above step through a patterning process.

As shown in FIG. 5, this step specifically comprises steps of:

S21, forming an amorphous silicon (a-Si) thin film. The methods for forming the amorphous silicon thin film include a Plasma Enhanced Chemical Vapor Deposition method and a Low Pressure Chemical Vapor Deposition method.

S22, performing a laser annealing process on the amorphous silicon thin film by using a mask plate 10 to form a low temperature poly-silicon thin film, wherein the mask plate 10 includes a transmissive region Q1 and a shielding region Q2 surrounding the transmissive region Q1, and two opposite sides of the shielding region Q2 adjacent to the transmissive region Q1 are in concave-convex shapes.

The step S22 specifically comprises: disposing the mask plate 10 directly above the base formed with the amorphous silicon thin film thereon first, wherein each of the two sides of the shielding region Q2 adjacent to the transmissive region Q1 of the mask plate 10, which is in concave-convex shape, has a plurality of peaks distributed at uniform intervals, and a distance between two adjacent peaks is from 0.3 μm to 2 μm. The concave-convex shape may be a triangular wave shape or a wave shape, and certainly, it may also be other shapes, such as a sine wave and a square wave.

Then, the amorphous silicon thin film is crystallized by using an excimer laser annealing process or a continuous wave solid-state laser annealing process through the mask plate 10. It should be understood that the laser may only pass through the transmissive region Q1 of the mask plate 10 to irradiate on the amorphous silicon thin film, and the amorphous silicon thin film irradiated by the laser will be melted to convert from solid state amorphous silicon thin film into a liquid silicon. Due to shielding of the shielding region Q2 of the mask plate 10, other regions of the amorphous silicon thin film are not irradiated by the laser, thus the amorphous silicon thin film in these regions are not melted and maintain a solid state, and a pattern of not melted amorphous silicon thin film 20 at a boundary of the not melted amorphous silicon thin film 20 and the melted amorphous silicon thin film is identical with the side of the shielding region Q2 of the mask plate 10 adjacent to the transmissive region Q1, which is in the concave-convex shape. The liquid silicon at the boundary of the not melted amorphous silicon thin film 20 and the melted amorphous silicon thin film is epitaxially grown along the peaks by taking the solid-state silicon at the boundary as crystal nucleuses at first to form a low temperature poly-silicon thin film 21. Assuming that the crystal nucleuses have the same growth speed, a position affecting a region away from the boundary most is a position of the crystal nucleus at a peak far away from the boundary, that is, each small circle at each peak as shown in FIG. 3. Therefore, distances between the peaks of the not melted amorphous silicon thin film 20 may be adjusted during manufacturing to adjust the grain size and grain boundary location, so as to improve the uniformity of the formed low temperature poly-silicon thin film 21.

Optionally, in the above step, a scanning direction of the laser is parallel to an orientation direction of peaks of the concave-convex shape, that is, the direction indicated by arrows at top of FIGS. 2-3. The reason for making the laser scan in a direction parallel to the orientation direction of peaks of the concave-convex shape is that what are in this direction are single grains, and the mobility of carriers may be increased significantly by pulling the single grains into straight lines, as shown in FIG. 3.

In the above step of performing the laser annealing process on the amorphous silicon thin film by using the mask plate 10, an energy density of the laser is preferably from 350 mJ/cm² to 550 mJ/cm² to ensure that the irradiated amorphous silicon thin film is completely melted. Certainly, the energy density of the laser may be adjusted according to the thickness of the amorphous silicon thin film.

In the step of performing the laser annealing process on the amorphous silicon thin film by using the mask plate 10, a pulse width of the laser is from 30 ns to 200 ns to ensure that the crystal nucleus has enough growth time in the horizontal direction (that is, the orientation direction of the peaks).

S23, removing at least a part, preferably all, of the amorphous silicon thin film 20 not being irradiated by the laser through a patterning process, the remained part of the amorphous silicon thin film 20 functions as the active layer. It should be understood that the active layer may be divided into a source contact area 31, a drain contact area 32 and a channel area 33 between the source contact area 31 and the drain contact area 32, wherein in a case that a part of the amorphous silicon thin film 20 not being irradiated by the laser is removed, it is required to ensure that a width of the formed amorphous silicon thin film 20 is larger than that of the channel area.

Step 3, forming a gate insulation layer on the base subjected to the above steps.

In this step, the gate insulation layer is formed by using a thermal growth method, an Atmospheric Pressure Chemical Vapor Deposition (APCVD) method, a Low Pressure Chemical Vapor Deposition (LPCVD) method, a Plasma Assisted Chemical Vapor Deposition (PACVD) method or a sputtering method.

Step 4, forming a pattern including a gate on the base subjected to the above steps through a patterning process.

In this step, a gate metal thin film is first formed by using a sputtering method, a thermal evaporation method, a Plasma Enhanced Chemical Vapor Deposition (PECVD) method, a Low Pressure Chemical Vapor Deposition (LPCVD) method, an Atmospheric Pressure Chemical Vapor Deposition (APCVD) method or an Electron Cyclotron Resonance Chemical Vapor Deposition (ECR-CVD) method, then a photoresist coating, an exposure, a development, an etching and a photoresist stripping are performed on the gate metal thin film to form the gate of the thin film transistor.

Step 5, forming a passivation layer and etching the passivation layer and the gate insulation layer to form vias corresponding to the source contact area and the drain contact area.

In this step, the passivation layer is formed by using a thermal growth method, an Atmospheric Pressure Chemical Vapor Deposition (APCVD) method, a Low Pressure Chemical Vapor Deposition (LPCVD) method, a Plasma Assisted Chemical Vapor Deposition (PACVD) method or a sputtering method, and the vias penetrating through the passivation layer and the gate insulation layer and corresponding to the source contact area and the drain contact area are formed through an etching process.

Step 6, forming a pattern including a source and a drain on the base subjected to the above steps through a patterning process, wherein a direction of a center connection line connecting centers of the source and the drain is parallel to the scanning direction of the laser.

A source-drain metal thin film is formed by using a sputtering method, a thermal evaporation method, a Plasma Enhanced Chemical Vapor Deposition (PECVD) method, a Low Pressure Chemical Vapor Deposition (LPCVD) method, an Atmospheric Pressure Chemical Vapor Deposition (APCVD) method or an Electron Cyclotron Resonance Chemical Vapor Deposition (ECR-CVD) method, then a photoresist coating, an exposure, a development, an etching and a photoresist stripping are performed on the source-drain metal thin film to form a pattern including the source and the drain of the thin film transistor, the source and the drain contact the source contact area and the drain contact area of the active layer through a corresponding via respectively.

So far, the manufacturing of the low temperature poly-silicon thin film transistor is completed.

Accordingly, this embodiment further provides a low temperature poly-silicon thin film transistor, which is manufactured by using the above manufacturing method. Since the grain size and grain boundary position of the low temperature poly-silicon thin film are improved, when the low temperature poly-silicon thin film as the active layer is applied to the low temperature poly-silicon thin film transistor, the electric characteristics of the low temperature poly-silicon thin film transistor can be enhanced.

### Third Embodiment

The present embodiment provides a display device comprising the above low temperature poly-silicon thin film transistor, therefore, the display effect of the display device in the present embodiment is better.

The display device may be any product or part which is provided with a display function such as a liquid crystal panel, an electronic paper, an organic light emitting diode (OLED) panel, a mobile phone, a tablet computer, a TV, a display, a notebook computer, a digital frame and a navigator.

It should be understood that, the foregoing embodiments are only exemplary embodiments used for explaining the principle of the present invention, but the present invention is not limited thereto. Various variations and improvements may be made by a person skilled in the art without departing from the protection scope of the present invention, and these variations and improvements also fall into the protection scope of the present invention.

1-18. (canceled)

19. A manufacturing method of a low temperature poly-silicon thin film, comprising steps of:
forming an amorphous silicon thin film on a base; and
performing a laser annealing process on the amorphous silicon thin film by using a mask plate to form a low temperature poly-silicon thin film, wherein
the mask plate includes a transmissive region and a shielding region surrounding the transmissive region, and two sides of the shielding region adjacent to the transmissive region are in concave-convex shapes.

20. The manufacturing method of a low temperature poly-silicon thin film of claim 19, wherein in the step of performing a laser annealing process on the amorphous silicon thin film by using a mask plate, a scanning direction of a laser is parallel to a orientation direction of peaks of the concave-convex shape.

21. The manufacturing method of a low temperature poly-silicon thin film of claim 19, wherein in the step of performing a laser annealing process on the amorphous silicon thin film by using a mask plate, an energy density of the laser is from 350 mJ/cm² to 550 mJ/cm².

22. The manufacturing method of a low temperature poly-silicon thin film of claim 21, wherein in the step of performing a laser annealing process on the amorphous silicon thin film by using a mask plate, a pulse width of the laser is from 30 ns to 200 ns.

23. The manufacturing method of a low temperature poly-silicon thin film of claiml 9, further comprising, before the step of forming an amorphous silicon thin film on a base, a step of forming a buffer layer on the base.

24. The manufacturing method of a low temperature poly-silicon thin film of claim 23, wherein the buffer layer comprises at least one of a silicon oxide layer and a silicon nitride layer.

25. The manufacturing method of a low temperature poly-silicon thin film of claim 23, wherein a thickness of the buffer layer is from 150 nm to 300 nm.

26. The manufacturing method of a low temperature poly-silicon thin film of claim 19, wherein the peaks of the concave-convex shape are distributed at uniform intervals and a distance between two adjacent peaks is from 0.3 μm to 2 μm.

27. The manufacturing method of a low temperature poly-silicon thin film of claim 19, wherein the concave-convex shape is a triangular wave shape or a wave shape.

28. The manufacturing method of a low temperature poly-silicon thin film of claim 19, wherein the laser annealing process is an excimer laser annealing process or a continuous wave solid-state laser annealing process.

29. A low temperature poly-silicon thin film, which is manufactured by using the manufacturing method of a low temperature poly-silicon thin film of claim 19.

30. A manufacturing method of a low temperature poly-silicon thin film transistor, comprising the manufacturing method of a low temperature poly-silicon thin film of claim 19.

31. A manufacturing method of a low temperature poly-silicon thin film transistor, comprising a step of forming an active layer, wherein the step of forming an active layer comprises steps of:
forming an amorphous silicon thin film on a base;
performing a laser annealing process on the amorphous silicon thin film by using a mask plate to form a low temperature poly-silicon thin film, wherein the mask plate includes a transmissive region and a shielding region surrounding the transmissive region, and two sides of the shielding region adjacent to the transmissive region are in concave-convex shapes; and
performing a patterning process on the low temperature poly-silicon thin film to form a pattern including the active layer.

32. The manufacturing method of a low temperature poly-silicon thin film transistor of claim 31, further comprising, before the step of forming an amorphous silicon thin film on a base, a step of forming a buffer layer on the base.

33. The manufacturing method of a low temperature poly-silicon thin film transistor of claim 13, wherein in the step of performing a laser annealing process on the amorphous silicon thin film by using a mask plate, a scanning direction of a laser is parallel to a orientation direction of peaks of the concave-convex shape.

34. The manufacturing method of a low temperature poly-silicon thin film transistor of claim 32, wherein in the step of performing a laser annealing process on the amorphous silicon thin film by using a mask plate, a scanning direction of a laser is parallel to a orientation direction of peaks of the concave-convex shape.

35. The manufacturing method of a low temperature poly-silicon thin film transistor of claim 33, further comprising, after the formation of the pattern including the active layer, a step of forming a pattern including a source and a drain by using a patterning process, wherein a direction of a center connection line connecting centers of the source and the drain is parallel to a scanning direction of the laser.

36. The manufacturing method of a low temperature poly-silicon thin film transistor of claim 34, further comprising, after the formation of the pattern including the active layer, a step of forming a pattern including a source and a drain by using a patterning process, wherein a direction of a center connection line connecting centers of the source and the drain is parallel to a scanning direction of the laser.

37. A low temperature poly-silicon thin film transistor, which is manufactured by using the manufacturing method of a low temperature poly-silicon thin film transistor of claim 30.

38. A display device comprising the low temperature poly-silicon thin film transistor of claim 37.
